(19) United States
(12) Patent Application Publication
(10) Pub. No.: US 2006/0060377 A1
(43) Pub. Date: Mar. 23, 2006

(54) Method of forming a multi-layer printed circuit board and the product thereof

(75) Inventors: Cheng-Hsien Chou, Tu-Cheng City (TW); Hung-Yi Yeh, Tu-Cheng City (TW); Chia-Hung Lin, Tu-Cheng City (TW); Jia-Ren Liang, Tu-Cheng City (TW)

Correspondence Address: TROXELL LAW OFFICE PLLC;Suite 1404, 5205 Leesburg Pike, Falls Church, VA, 22041, US

(73) Assignee: Unitech Printed Circuit Board Corp.

(21) Appl. No.: 11/270,490

(22) Filed: Nov. 10, 2005

Related U.S. Application Data
(62) Division of application No. 10/623,592, filed on Jul. 22, 2003.

(51) Int. Cl. H05K 1/03

(52) U.S. Cl. 174/255; 174/258

(57) ABSTRACT

In manufacturing a multi-layer printed circuit board (PCB), different processes are employed for forming inner and outer circuit layers of the PCB. Particularly, second and third inner circuit layers of the multi-layer PCB are formed with the resin build-up process through liquid epoxy coating or dry film type epoxy laminating to enable refinement of circuits provided thereon, and two outer circuit layers of the multi-layer PCB are formed on copper clad and insulating dielectric with the lamination process to improve the thermal resistance, copper peel strength, structural stiffness, thermal stress reliability, and size stability of the completed PCB. The multi-layer PCB manufactured with two different processes has improved quality and reliability, and may be manufactured at reduced cost.

### FIELD OF THE INVENTION

The present invention relates to a method of forming a multi-layer printed circuit board (PCB) and the product thereof, and more particularly to a multi-layer PCB that has inner circuit layers formed with a resin build-up process and outer circuit layers formed with a lamination process to eliminate problems caused by forming the multi-layer PCB with only one single type of manufacturing process and therefore has effectively upgraded quality and reduced manufacturing cost.

### BACKGROUND OF THE INVENTION

To meet the requirements of various kinds of existing electronic apparatus to be thin, light, small, and compact, all electronic components and the printed circuit board (PCB) in the electronic apparatus for the electronic components to mount thereon are correspondingly reduced in size and weight. In other words, it is an increasingly urgent requirement for the PCB to have highly densely distributed circuits thereon. Currently, there are two ways for increasing the circuit density on the PCB. The first way is to increase the density of circuits on each circuit layer of the PCB, and the second way is to form a multi-layer PCB by stacking additional circuit layers on one or more cores of the PCB. The second way of forming a multi-layer PCB may be further divided into two types, namely, a lamination process, in which copper clad and dielectric material are laminated, and a resin build-up process, in which no copper clad but only bare dielectric material is coated or laminated. More particularly, the lamination process includes the steps of forming circuit layers on one or more cores; applying a laminating dielectric, such as a film formed of epoxy resin and fiberglass, between two inner cores or at an inner side of each outer layers of copper clad to form a dielectric layer; and heating and laminating multiple layers of cores to form a multi-layer PCB. And, the resin build-up process includes the steps of forming circuit layers on one or more cores; applying a dielectric, such as resin, on the cores to form the dielectric layers through liquid epoxy coating or dry film type epoxy laminating; forming another circuit layer on each dielectric layer; and repeating the steps of forming the dielectric layer and the circuit layer so that the dielectric layer and the circuit layer are alternately stacked to form a multi-layer PCB.

Technically speaking, the above-mentioned two processes for forming the multi-layer PCB have their respective advantages. For example, the resin build-up process using the resin material as the dielectric layers is more useful in the refinement of the circuit layers. On the other hand, the lamination process using the reinforced-fiber-contained dielectric, such as film formed of epoxy resin and fiberglass, as the laminating dielectric may advantageously improve the peel strength, thermal stress reliability, and size stability of the produced multi-layer PCB.

Moreover, in the circuit design for multi-layer PCB, it is necessary to establish interconnection between two adjacent circuit layers at some specific contacts thereof to enable electrical conduction. Currently, there are many different ways for establishing the above-mentioned interconnection and electrical conduction between two circuit layers on the multi-layer PCB. For example, laser or mechanical drilling may be employed in the multi-layer PCB forming process to form conductive holes at interconnected areas, and then, one of many known ways may be employed to form an electrically conductive plating layer on each hole. Alternatively, in the lamination process, solid copper column plating may be implemented at an area on one circuit layer to directly connect with a contact on another circuit layer.

A multi-layer PCB having good quality must have predetermined thermal resistance, copper peel strength, and stiffness. Since outer circuit layers on the multi-layer PCB are generally applied with a layer of solder mask, on which electronic components are mounted by way of insertion or surface mounting technique, they must have relatively enhanced copper peel strength to avoid undesired peeling of the electronic components and circuits off the PCB. When the conventional resin build-up process is employed to form the outer circuit layers, the latter shall have lower thermal resistance, stiffness, and, particularly, copper peel strength as compared with that formed with the lamination process. Moreover, the application of solder mask and the mounting of electronic components on the outermost circuit layers (or the first layers) results in limited space and area for the circuits. Under this condition, a part of the connecting circuits must be moved to inner circuit layers, that is, the second or even the third inner circuit layers. This necessitates the refinement of circuits on the second and the third inner circuit layers.

When the conventional lamination process is employed to form the inner circuit layers, it is necessary to form an electrically conductive plating layer on all conductive holes formed on the previously laminated copper clad, resulting in an increased thickness of the finished circuit layers to cause difficulties in the refinement of circuits on the second and/or the third inner circuit layers. On the other hand, since it is not necessary to refine circuits on other layers at inner sides of the third layers or the inner circuit layers directly formed on the cores, these inner circuit layers are usually formed with the lamination process without adversely affecting the structural quality of the multi-layer PCB.

Currently, most multi-layer printed circuit boards are manufactured with only one type of process to form multiple layers. For instance, in a VIL process developed by JVC of Japan, the way of liquid epoxy coating is employed to form the inner and the outer circuit layers of the multi-layer PCB. That is, both the outer and the second and third inner circuit layers are formed with the resin build-up process. After all the layers of the multi-layer PCB are formed, the outmost layers are applied with the solder mask. While the outer circuit layers formed with the VIL process through liquid epoxy coating, drying, and copper plating do satisfy the requirement of circuit refinement, they have a reduced reliability as compared with the outer circuit layers formed with the lamination process. In other words, in the multi-layer PCB produced with the VIL process, since both the inner and the outer circuit layers are formed through liquid epoxy coating, the completed PCB has apparently lower peel strength and thermal strength reliability as compared with that formed with the lamination process. The multi-layer PCB made with the VIL process also has reduced stiffness to result in user's doubt and accordingly lowered acceptance.

From the above analysis, it is found that any multi-layer PCB formed with only one of the two conventional processes could not satisfy the requirements for thermal resistance, copper peel strength, stiffness, and refinement of circuits on the second and third inner circuit layers at the same time.

It is therefore tried by the inventor to develop a method of forming a multi-layer PCB that would satisfy the requirements for thermal resistance, copper peel strength, stiffness, and refinement of circuits on the second and third inner circuit layers at the same time.

### SUMMARY OF THE INVENTION

In one aspect of the present invention, there is provided a method of forming a multi-layer printed circuit board (PCB) that combines advantages obtainable from the resin build-up process and the lamination process.

In another aspect of the present invention, there is provided a multi-layer PCB having combined advantages obtainable from the resin build-up process and the lamination process.

According to the method of the present invention, different processes are employed for forming inner and outer circuit layers of a multi-layer PCB. More particularly, the second and third inner circuit layers of the multi-layer PCB are formed with the resin build-up process using liquid epoxy coating or dry film type epoxy laminating, and the outmost circuit layers of the multi-layer PCB are formed with the lamination process. Thus, circuits on the second and third inner circuit layers formed with the resin build-up process have upgraded refinement to satisfy the circuit design requirement of a multi-layer PCB, and the completed multi-layer PCB has improved overall thermal resistance, copper peel strength, structural stiffness, thermal stress reliability, and size stability.

The multi-layer PCB manufactured with the method of the present invention has quality and reliability superior to that of a multi-layer PCB having inner and outer circuit layers completely formed with only one type of process, and may be manufactured at reduced cost.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a sectional view of a one-core eight-layer printed circuit board (PCB) according to a first embodiment of the present invention;

FIGS. 2A-2K shows different steps included in the method of the present invention for forming the 8-layer PCB of FIG. 1;

FIG. 3 is a sectional view of a two-core 8-layer PCB according to a second embodiment of the present invention;

FIG. 4 is a sectional view of a two-core 8-layer PCB having solid copper column plating according to a third embodiment of the present invention;

FIG. 5 is a sectional view of a two-core six-layer PCB according to a fourth embodiment of the present invention;

FIG. 6 is a sectional view of a three-core ten-layer PCB according to a fifth embodiment of the present invention; and

FIG. 7 is a sectional view of a one-core 6-layer PCB according to a sixth embodiment of the present invention.

### DETAILED DESCRIPTION OF THE PREFERRED EMBODIMENTS

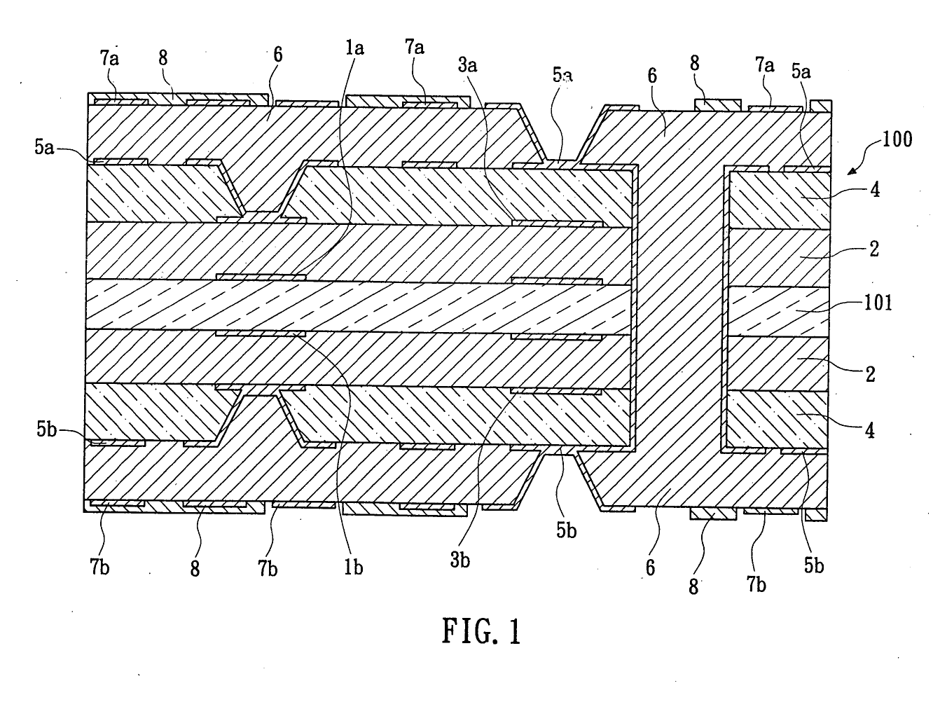

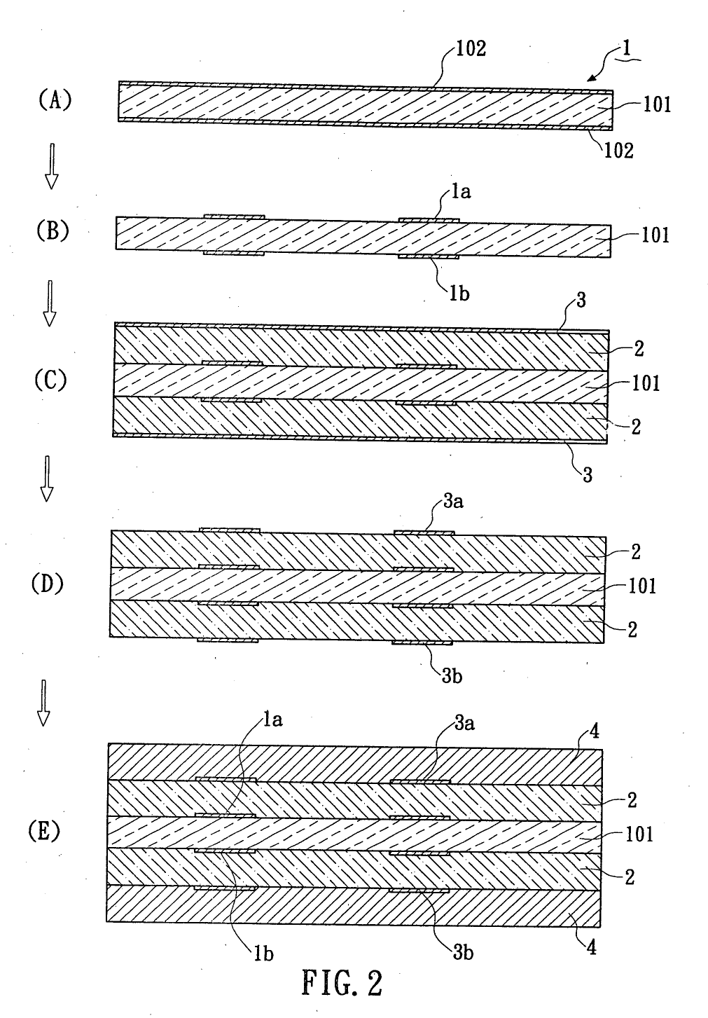

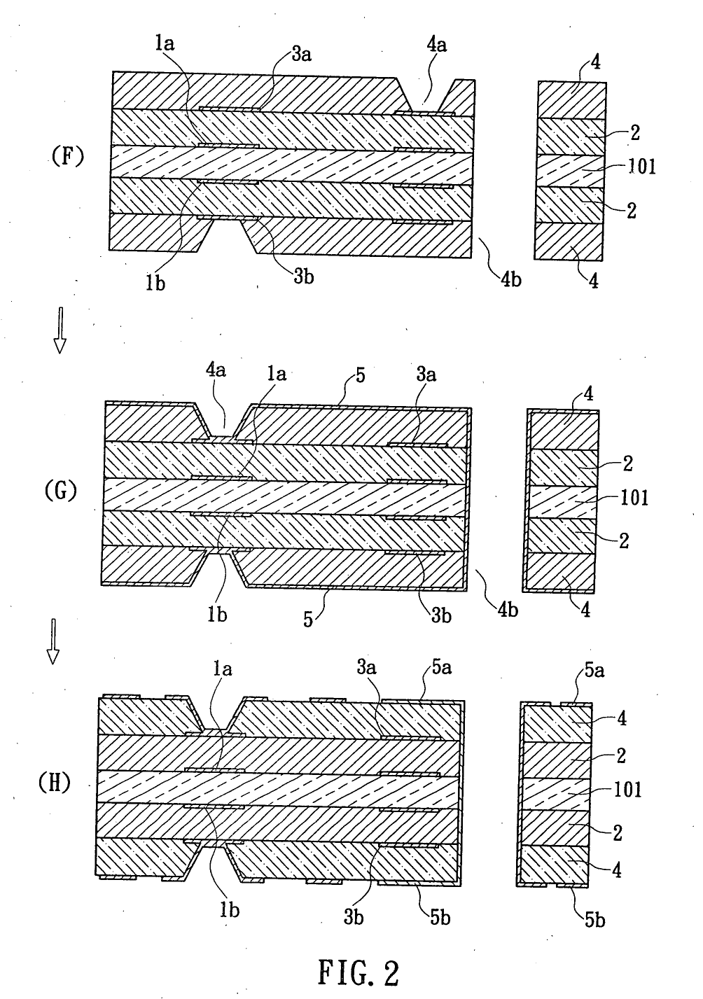

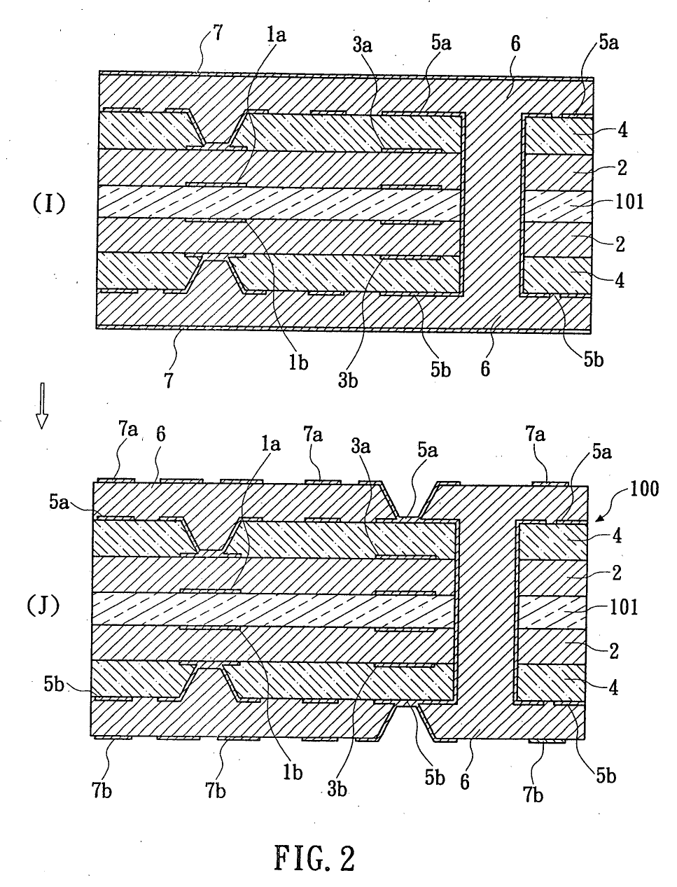

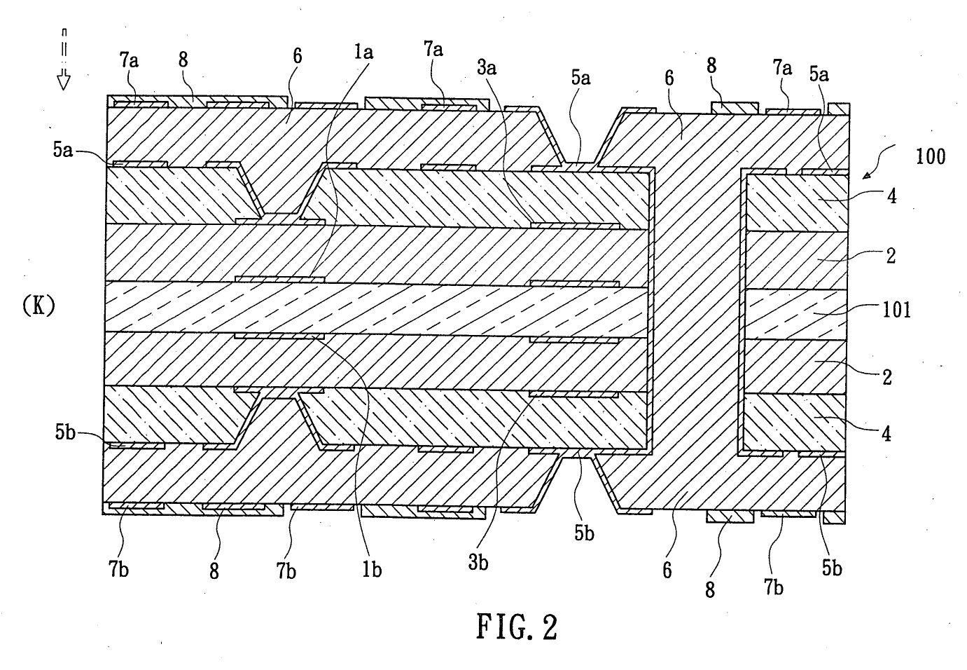

Please refer to FIG. 1 that is a sectional view of a one-core eight-layer printed circuit board (PCB) 100 according to an embodiment of the present invention, and to FIGS. 2A to 2K that shows steps included in a method of the present invention for forming the multi-layer PCB 100 of FIG. 1.

In the first step of the method of the present invention as shown in FIG. 2A, a core 1 is prepared. The core 1 is a thin compound plate having an inner layer 101 made of a prepreg material (that is, a resin-impregnated fiberglass fabric), and two copper clad layers 102 provided on two outer sides of the inner layer 101.

In the second step shown in FIG. 2B, a circuit formation is performed on the two copper clad layers 102 of the core 1 by way of etching to form two circuit layers 1a, 1b on the two outer sides of the inner layer 101, respectively.

In the third step shown in FIG. 2C, a laminating dielectric layer 2 that may be formed from the prepreg material or an aramid fiber material and a copper clad layer 3 are sequentially formed on each of the two circuit layer 1a, 1b by way of lamination, so that a four-layer PCB is formed.

In the fourth step shown in FIG. 2D, a circuit formation is performed on the copper clad layers 3 to form another two circuit layers 3a, 3b on outer sides of the two dielectric layers 2.

In the fifth step shown in FIG. 2E, two resin layers 4 are separately formed on the two circuit layers 3a, 3b by way of applying a dielectric material, such as epoxy, on outer sides of the two circuit layers 3a, 3b. More specifically, the resin layers 4 are formed with the resin build-up process through liquid epoxy coating or dry film type epoxy laminating.

In the sixth step shown in FIG. 2F, necessary conductive holes 4a, 4b are formed on the resin layers 4 by performing laser drilling and mechanical drilling, respectively.

In the seventh step shown in FIG. 2G, the PCB obtained in the sixth step is plated with copper to form a copper-plating layer 5 on all outer surfaces of the PCB.

In the eighth step shown in FIG. 2H, the circuit formation by way of etching is performed on the copper-plating layer 5 to form two additional circuit layers 5a, 5b.

In the ninth step shown in FIG. 2I, another two laminating dielectric layers 6, which may be formed from the prepreg material or the aramid fiber material, and another two copper clad layers 7 are sequentially formed on outer sides of the two circuit layer 5a, 5b by way of lamination, so that an eight-layer PCB is formed.

In the tenth step shown in FIG. 2J, different operations, such as window formation, laser drilling, plating, and etching, are performed on the copper clad layers 7 to form circuit layers 7a, 7b on outer sides of the two laminating dielectric layers 6.

In the eleventh step shown in FIG. 2K, necessary operations, such as applying solder mask 8 or plating gold and spraying tin, are performed on the two circuit layers 7a, 7b to complete the eight-layer PCB 100. On the outmost layers, that is, the circuit layers 7a and 7b, electronic components are mounted or assembled.

In the above steps shown in FIGS. 2A to 2K, some operations, including laminating, liquid epoxy coating, dry film type epoxy laminating, laser drilling, mechanical drilling, copper plating, etching, and applying solder mask, may be done with existing techniques and apparatus. And, for the purpose of the 8-layer PCB 100, the circuit layers 7a and 7b shall be referred to as the outer circuit layers that form a first layer of the PCB 100, while the circuit layers 1a and 1b, 3a and 3b, and 5a and 5b shall be referred to as the inner circuit layers. Wherein, the inner circuit layers 5a 5b and the inner circuit layers 3a and 3b form a second and a third layer, respectively, of the PCB 100, and are also referred to as the second and the third inner circuit layer, respectively, hereinafter.

The present invention is characterized in that the resin build-up process and the lamination process are employed to form the inner circuit layers and the outer circuit layers, respectively, of the 8-layer PCB 100. More specifically, the inner circuit layers, such as the second inner circuit layers 5a and 5b, which require refinement of circuits are formed by using a resin material, such as epoxy, as the dielectric to form the resin layers 4 with the resin build-up process through liquid epoxy coating or dry film type epoxy laminating, and then forming the inner circuit layers 5a and 5b. Thereafter, the dielectric layers 6 using the prepreg or the aramid fiber material as the dielectric and the outer circuit layers 7a, 7b are formed with the lamination process.

By using the resin build-up process and the lamination process to form different layers on the same one multi-layer PCB, the completed multi-layer PCB 100 is able to include advantages obtainable from the two processes. For example, the second inner circuit layers 5a and 5b of the multi-layer PCB 100 formed with the resin build-up process have upgraded circuit refinement to satisfy the circuit design requirement of the multi-layer PCB, and the outer circuit layers 7a and 7b of the multi-layer PCB 100 formed with the lamination process have improved thermal resistance, copper peel strength, stiffness, thermal stress reliability, and size stability. Therefore, the fully completed 8-layer PCB 100 has a quality reliability superior to that of a multi-layer PCB formed with only one of the conventional forming processes. Moreover, since at least some of the inner circuit layers, for example, the second inner circuit layers 5a and 5b, use resin layers 4 as the dielectric layers, and the cost for the resin material is much lower than the cost for the prepreg or the aramid fiber material used as the laminating dielectric layers 6, the multi-layer PCB made according to the method of the present invention has reduced material cost to lower the overall manufacturing cost thereof.

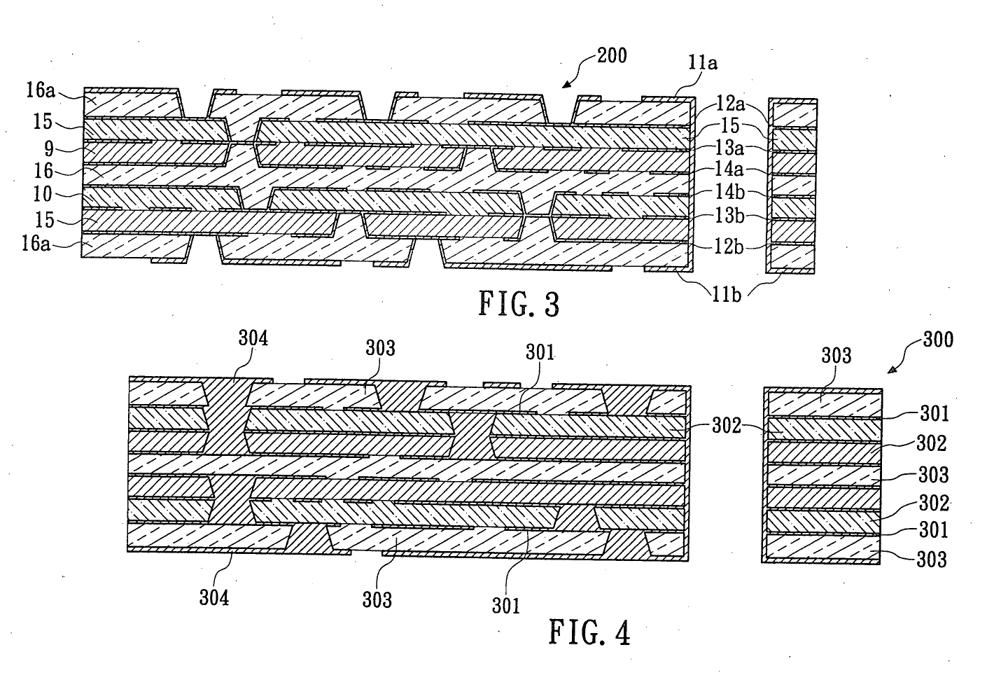

Please refer to FIG. 3 that shows a two-core eight-layer PCB 200 formed with the method of the present invention. As shown, the 8-layer PCB 200 mainly includes two cores 9 and 10, two outer circuit layers 11a and 11b, and total six layers of inner circuit layers 12a and 12b, 13a and 13b, and 14a and 14b, and total five dielectric layers 16, 15, and 16a from inner to outer side. The two cores 9 and 10 are structurally identical to the core 1 of the 8-layer PCB 100 of FIG. 1. Three of the five dielectric layers 16 and 16a are formed with the lamination process and use the same prepreg or aramid fiber material as that for the dielectric layers 6 of the 8-layer PCB 100. The other two dielectric layers 15 are formed with the resin build-up process using the same manner and the same epoxy material as that for the resin layers 4 of the 8-layer PCB 100. More specifically, the method of forming the 8-layer PCB 200 includes the steps of (1) forming a resin dielectric layer 15 and three circuit layers 12a, 13a, 14a on the core 9, and forming another resin dielectric layer 15 and another three circuit layers 12b, 13b, 14b on the core 10 to produce two 3-layer PCB's; (2) forming a laminating dielectric layer 16 between the two 3-layer PCB's obtained in the step (1), and forming two laminating dielectric layers 16a at outer sides of the two circuit layers 12a, 12b; (3) performing the lamination process to laminate the two 3-layer PCB's formed on the two cores 9, 10, the middle dielectric layer 16, the two outer dielectric layers 16a, and two copper clad layers formed at outer sides of the two outer dielectric layers 16a, so as to form an eight-layer PCB; (4) performing different operations, such as window formation, laser drilling, plating, and etching, on the copper clad layers to form circuit layers 11a and 11b on outer sides of the two dielectric layers 16a; and (5) performing operations, such as applying solder mask or plating gold and spraying tin, on the circuit layers 11a, 11b to complete the eight-layer PCB 200.

The method for forming the 8-layer PCB 200 has characteristics generally the same as that of the 8-layer PCB 100. More specifically, the resin build-up process and the lamination process are employed to form the inner circuit layers and the outer circuit layers, respectively, of the 8-layer PCB 200. Wherein, the inner circuit layers, such as the second inner circuit layers 12a and 12b, which require refinement of circuits are formed by using a resin material, such as epoxy, as the dielectric to form the resin layers 15 on the cores 9 and 10 with the resin build-up process through liquid epoxy coating or dry film type epoxy laminating, and then forming the inner circuit layers 12a and 12b. Thereafter, the dielectric layers 16a using the prepreg or the aramid fiber material as the dielectric, and the outer circuit layers 11a, 11b are formed with the lamination process.

By using the resin build-up process and the lamination process to form different layers on the same one multi-layer PCB, the completed multi-layer PCB 200 is able to include advantages obtainable from the two processes. For example, the second inner circuit layers 12a and 12b of the multi-layer PCB 200 formed with the resin build-up process have upgraded circuit refinement to satisfy the circuit design requirement of the multi-layer PCB, and the outer circuit layers 11a and 11b of the multi-layer PCB 200 formed with the lamination process have improved thermal resistance, copper peel strength, stiffness, thermal stress reliability, and size stability. Therefore, just like the 8-layer PCB 100, the fully completed 8-layer PCB 200 has a quality reliability superior to that of a multi-layer PCB formed with only one of the two conventional forming processes, and have a reduced manufacturing cost.

The method of forming a multi-layer PCB and the produced multi-layer PCB according to the present invention have at least the following advantages:
1. The resin build-up process and the lamination process are employed to form the inner and the outer circuit layers, respectively, on the same one multi-layer PCB, so that the completed multi-layer PCB includes advantages obtainable from the two processes.
2. The method of the present invention includes selection and combination of different technical means, and all steps included in the method may be accomplished with existing technical skills and apparatus to reduce costs of purchasing new apparatus. Moreover, the quality of the produced multi-layer PCB could be stably controlled to provide enhanced competition ability and achieve the purpose of mass-production.
3. In the multi-layer PCB produced with the method of the present invention, the outer circuit layers thereof are formed with the lamination process to improve the thermal resistance, copper peel strength, stiffness, and thermal stress reliability of the PCB. The multi-layer PCB of the present invention is therefore superior to that produced with the conventional VIL process developed by JVC of Japan.
4. In the multi-layer PCB produced with the method of the present invention, some of the inner circuit layers thereof are formed with the resin build-up process to upgrade the circuit refinement thereof, particularly the circuit refinement of the second inner circuit layer, to satisfy the circuit design requirement of the multi-layer PCB.

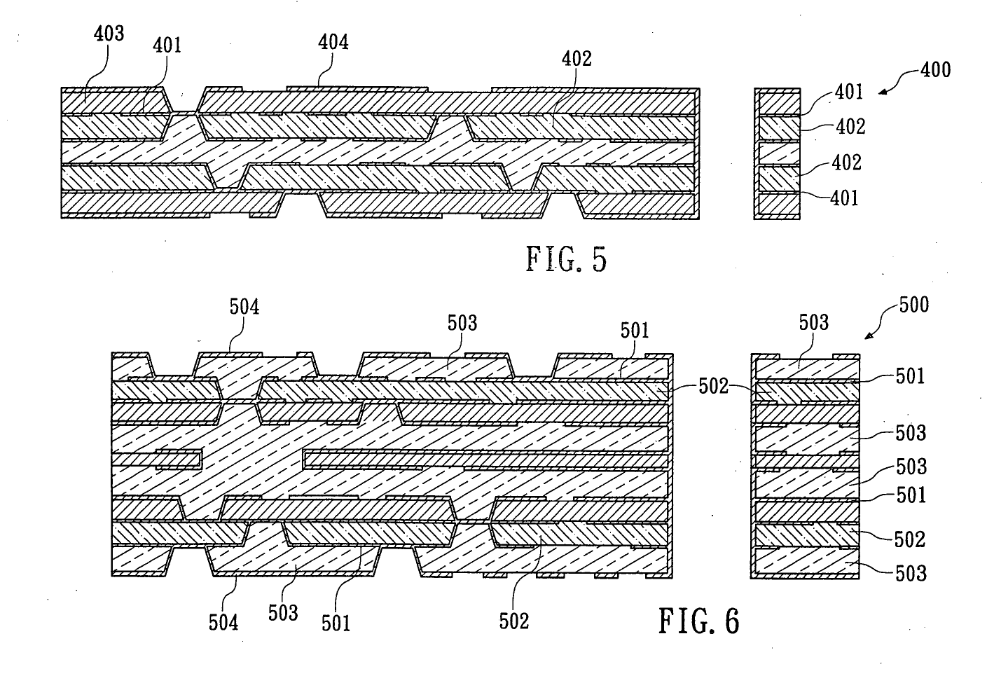

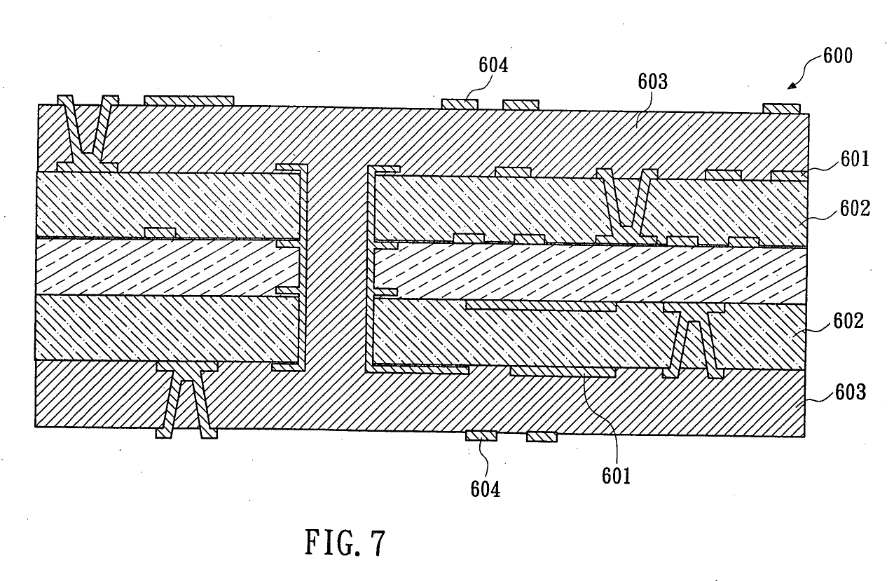

FIG. 4 shows a two-core 8-layer PCB 300 with electrically conductive solid copper column plating, FIG. 5 shows a two-core 6-layer PCB 400, FIG. 6 shows a 3-core 10-layer PCB 500, and FIG. 7 shows a one-core 6-layer PCB 600. All of these multi-layer PCB's 300, 400, 500, and 600 are made with the method of the present invention, and have second inner circuit layers 301, 401, 501, and 601 formed with the resin build-up process to locate at outer sides of resin layers 302, 402, 502, and 602, respectively, and have the advantage of highly refined circuits. On the other hand, the multi-layer PCB's 300, 400, 500, and 600 have dielectric layers 303, 403 (which are also the inner material of the cores), 503, and 603 made of the prepreg or the aramid fiber material to provide the completed multi-layer PCB with enhanced physical properties, including improved thermal resistance, copper peel strength, stiffness, and thermal stress reliability.

1-6. (canceled)

7. A multi-layer printed circuit board (PCB), comprising at least one core, multiple circuit layers sequentially provided at each outer side of said core to include at least an outer circuit layer forming a first layer of said PCB and two inner circuit layers forming a second and a third inner circuit layer of said PCB, and multiple dielectric layers, each of which is provided between two said circuit layers that are adjacent to each other; said multi-layer PCB being characterized in that at least one resin layer is formed between said second and said third inner circuit layers of said PCB to serve as said dielectric layer, that said second inner circuit layer is formed on said resin layer to enable refinement of circuits thereon, that an outmost one of said dielectric layers located between said outer circuit layer and said second inner circuit layer is formed of a resin material containing a reinforcing fiber material, and that said outer circuit layer is formed on said dielectric layer of said resin material containing a reinforcing fiber material by way of lamination to possess enhanced peel strength.

8. The multi-layer PCB as claimed in claim 7, wherein said resin layer is formed of epoxy.

9. The multi-layer PCB as claimed in claim 7, wherein said resin layer formed between said second and said third layer of said PCB is formed with a resin build-up process through liquid epoxy coating.

10. The multi-layer PCB as claimed in claim 7, wherein said resin layer formed between said second and said third layer of said PCB is formed with a resin build-up process through dry film type epoxy laminating.

11. The multi-layer PCB as claimed in claim 7, wherein said resin material containing a reinforcing fiber material is a prepreg material, that is, a resin-impregnated fiberglass fabric.

12. The multi-layer PCB as claimed in claim 7, wherein said resin material containing a reinforcing fiber material is an aramid fiber materia.
